(19) United States
(12) Patent Application Publication
(10) Pub. No.: US 2025/0194149 A1
(43) Pub. Date: Jun. 12, 2025

(54) CONTACT EXTENSION FOR ADDITIONAL WIRING PATHS

(71) Applicant: International Business Machines Corporation, Armonk, NY (US)

(72) Inventors: Liqiao Qin, Albany, NY (US); Tao Li, Slingerlands, NY (US); Ruilong Xie, Niskayuna, NY (US); Leon Sigal, Monsey, NY (US)

(21) Appl. No.: 18/533,747

(22) Filed: Dec. 8, 2023

(51) Int. Cl. H01L 29/417; H01L 21/8238; H01L 23/48; H01L 27/092; H01L 29/06; H01L 29/423; H01L 29/66; H01L 29/775; H01L 29/786

(52) U.S. Cl. CPC H10D 30/6729; H01L 23/481; H10D 30/014; H10D 30/43; H10D 30/6735; H10D 30/6757; H10D 62/121; H10D 84/017; H10D 84/0186; H10D 84/038; H10D 84/85

(57) ABSTRACT

A semiconductor device includes source/drain regions disposed at a first level and contacts connecting to the source/drain regions on a first side of the source/drain regions. A contact extension includes end portions connected to the contacts and a length spanning a distance between the contacts. A cut plug is disposed through the length and electrically isolates portions of the contact extension to form signal paths to the source/drain regions from a metal layer above the first level.

### BACKGROUND

The present invention generally relates to semiconductor devices and processing methods, and more particularly to field effect transistors (FETs) with frontside contacts extended to enable additional wiring.

Areal density for semiconductor devices on a chip is a consistent concern. With shrinking node sizes, the close proximity of transistors as well as metal structures connecting them becomes a greater concern, since positioning transistors in such close proximity can potentially cause failures. This places spatial and electrical constraints on chip designs that can make it challenging to provide required performance. Contacts, interconnects and metal lines have become increasingly more difficult to route through and to source/drain areas in wiring structures of a semiconductor device. Contact and wire routing density have increasingly less space and therefore fewer options are available.

Therefore, a need exists to employ vertical space more efficiently in a semiconductor device. A further need exists for extending contacts to permit greater routing flexibility in wiring structures.

### SUMMARY

In accordance with an embodiment of the present invention, a semiconductor device includes source/drain regions disposed at a first level and contacts connecting to the source/drain regions on a first side of the source/drain regions. A contact extension includes end portions connected to the contacts and a length spanning a distance between the contacts. A cut plug is disposed through the length and electrically isolates portions of the contact extension to form signal paths to the source/drain regions from a metal layer above the first level.

In some embodiments, the contacts and the contact extension can share a top surface. The length of the contact extension can span over at least one source/drain region. The at least one source/drain region can include a contact at a second side opposite the first side. The cut plug can be formed through a via, and the via can be divided such that portions of the via are electrically isolated from one another and disposed within the at least two signal paths. The cut plug can be formed between two metal lines of the metal layer above the first level. The contacts and the contact extension can be integrally formed.

In accordance with another embodiment of the present invention, a semiconductor device includes a central source/drain region disposed between outer source/drain regions at a first level and contacts connecting to the outer source/drain regions on a first side of the outer source/drain regions. A contact extension has end portions connected to the contacts and a length spanning a distance between the contacts and over the central source/drain region. A via connects the contact extension to upper metal structures. A cut plug is disposed through the via and the length to electrically isolate portions of the via and the contact extension to provide at least two signal paths to the outer source/drain regions from the upper metal structures above the first level.

In some embodiments, the contacts and the contact extension can share a top surface. The length of the contact extension can span over at least one source/drain region. The central source/drain region can include a contact at a second side opposite the first side. The upper metal structures can include metal lines, and the cut plug can be formed between two metal lines above the first level. The contacts and the contact extension can be integrally formed.

In accordance with another embodiment of the present invention, a method for fabrication of a semiconductor device includes opening up contact openings in a dielectric layer to expose outer source/drain regions on a first side at a first level; patterning a contact extension opening in communication with the contact openings in the dielectric layer, the contact extension opening spanning over a central source/drain region disposed between the outer source/drain regions; forming contacts in the contact openings and a contact extension in the contact extension opening; forming a via that connects the contact extension to upper metal structures; forming metal lines for the upper metal structures that connect to the via; subtractive etching a cut between the metal lines through the via and through the contact extension; and filling the cut with a dielectric material to electrically isolate portions of the via and the contact extension to form at least two signal paths to the outer source/drain regions from the upper metal structures above the first level.

In other methods, forming contacts in the contact openings and the contact extension in the contact extension opening can include filling the contact openings and the contact extension opening with conductive material and planarizing the conductive material to form a shared top surface for the contacts and the contact extension. Filling the cut with the dielectric material can include dividing the via such that portions of the via are disposed in separate signal paths. The contacts and the contact extension can be integrally formed. The contacts and the contact extension can be disposed within a same level. The via can include a merged via having a portion over the contact extension and a portion over one of the outer source/drain regions. A contact can be formed to connect to the central source/drain region at a second side opposite the first side. Forming the contact can include exposing the central source/drain region on the second side, gouging the central source/drain region on the second side and forming the contact in a gouged portion of the central source/drain region.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows a cross-sectional view, taken at section line Y as shown in an inset (and referred to as section Y), of a semiconductor device having outer source/drain regions exposed by opening up contact holes or openings, in accordance with an embodiment of the present invention;

FIG. 2 shows a cross-sectional view, taken at section line Y, of the semiconductor device having a contact extension opening formed, in accordance with an embodiment of the present invention;

FIG. 3 shows a cross-sectional view, taken at section line Y, of the semiconductor device having contacts and a contact extension formed, in accordance with an embodiment of the present invention;

FIG. 4 shows a cross-sectional view, taken at section line Y, of the semiconductor device having a via and metal lines formed for upper metal structures, in accordance with an embodiment of the present invention;

FIG. 5 shows a cross-sectional view, taken at section line Y, of the semiconductor device having a plug cut subtractively etched through the via and through the contact extension from in between upper layer metal lines, in accordance with an embodiment of the present invention;

FIG. 6 shows a cross-sectional view, taken at section line Y, of the semiconductor device having a dielectric plug formed in the plug cut, in accordance with an embodiment of the present invention;

FIG. 7 shows a cross-sectional view, taken at section line Y, of the semiconductor device having a portion of the substrate removed to an etch stop layer, in accordance with an embodiment of the present invention;

FIG. 8 shows a cross-sectional view, taken at section line Y, with the etch stop layer and a remaining portion of the substrate removed and filled with a dielectric material, in accordance with an embodiment of the present invention;

FIG. 9 shows a cross-sectional view, taken at section line Y, with a contact opening opened up to expose a central source/drain region and gouges formed in the central source/drain region, in accordance with an embodiment of the present invention;

FIG. 10 shows a cross-sectional view, taken at section line Y, with gouges formed in the central source/drain region, in accordance with an embodiment of the present invention;

FIG. 11 shows a cross-sectional view, taken at section line Y, with contact openings filled including gouge portions of the contacts and a backside interconnect layer formed, in accordance with an embodiment of the present invention; and

FIG. 12 shows a flow chart for methods for fabricating a semiconductor, in accordance with an embodiment of the present invention.

### DETAILED DESCRIPTION

In accordance with embodiments of the present invention, devices and methods are described which more efficiently utilize vertical space in devices with a backside power distribution network (BSPDN). In one embodiment, source/drain (S/D) regions connected from a backside may not need to be connected from a frontside (or vice versa). This makes a contactless region adjacent to the S/D regions available for use in other capacities. In one embodiment, wire routing flexibility is increased by utilizing the contactless region to provide a contact extension, which can be connected to another metal layer, e.g., the M1 metal layer, to make use of the unused space. As M1 metal layer pitch continues to scale down, a contact that can be extended across vacant spaces on lower levels needs to be protected from shorting to nearby contacts or conductive structures. In accordance with embodiments of the present invention, a subtractive metal etch can be employed to address the challenge of protecting the contact extension from shorting. In one embodiment, the subtractive metal etch cuts an upper level contact, after it was previously formed, to divide the upper level contact into two portions. A cut formed in the upper level contact by the subtractive metal etch is filled with a dielectric material. The two portions of the divided contact are electrically isolated from one another and can then be employed in two separate circuits. It should be understood that the upper level contact can be divided into more than two portions.

In embodiments of the present invention, a contact extension bridges over a vacant space not utilized by a S/D region. The contact extension can include a metal wire or line that connects to two or more contacts. The contact extension can be formed integrally with contacts to which the contact extension is connected, or the contact extension can be formed after the contacts, to which the contact extension is connected, are formed. A dielectric cut structure can be formed in between S/D contacts and through the contact extension. The dielectric cut structure can be disposed in between two upper layer metal lines and in between two vias or divided portions of a contact that can connect the upper metal layer (to a metal line, e.g., M1) to the contact extension and/or connect the upper metal layer to a S/D contact directly.

As a result of the subtractive metal dielectric cut structure, the upper metal line has a positive taper (opens up), which indicates the metal line has been patterned using a subtractive metal etch. In addition, at least a first sidewall of a via connecting to the upper metal line has a negative taper, which indicates the via has been patterned using damascening, and at least a first sidewall of the M1, a second sidewall of the via, a first sidewall of the contact extension follows the same sidewall taper angle, indicating it has been patterned through a via cut etch. In an embodiment where the S/D region is connected to a backside contact, the contact extension can fly over or bridge over at least a topside of the S/D region.

In one embodiment, a method for forming a semiconductor device includes completing front end of line (FEOL) processing to form S/D regions, an interlevel dielectric (ILD) and middle of the line (MOL) contacts. The contacts are patterned into and through the ILD. Contact extension patterning can take place concurrently or in a separate process step. Then, MOL contacts and contact extension metallization are performed. Additional ILD deposition is followed by merged via patterning and metallization. The merged via is large enough to be divided to form at least two portions. Upper layer metal deposition is performed followed by subtractive patterning to form metal lines (e.g., M1 metal lines).

A subtractive metal etch forms an opening through the merged via (dividing the via) and through the contact extension to form a cut. The opening is formed between spaces in the metal line (M1) pitch. An ILD fill is performed which fills the cut. This results in at least two electric paths. Processing continues with back end of the line (BEOL) structure formation. A carrier wafer is bonded and a wafer flip is performed so that backside contacts can be formed. This can include substrate removal, backside ILD deposition and backside contact patterning. Placeholders are removed from the contact holes and optional gouging of the source/drain regions is performed prior to a pre-silicide clean. Backside contacts are formed followed by backside interconnects.

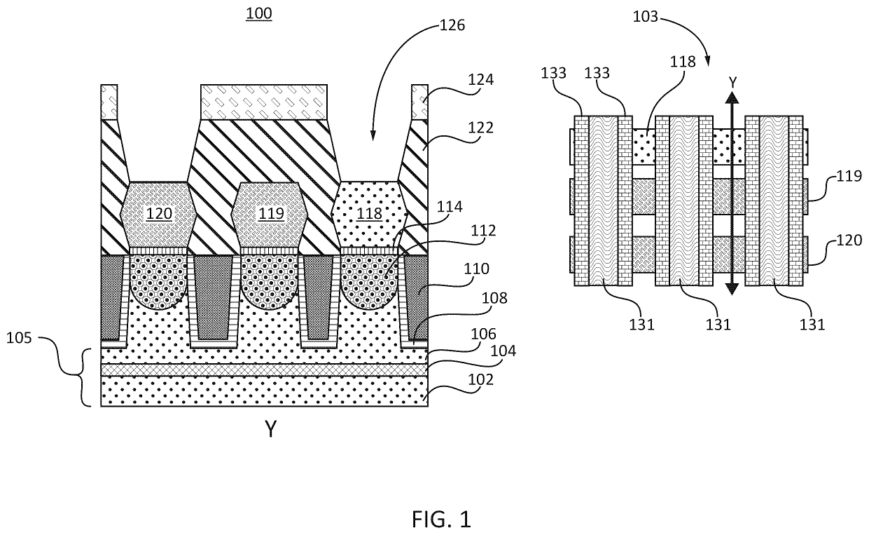

Referring now to the drawings in which like numerals represent the same or similar elements and initially to FIG. 1, devices and methods for manufacturing a backside power distribution network (BSPDN) device are shown in accordance with embodiments of the present invention. A wafer 100 includes a substrate 105 having multiple layers on which the regular BSPDN device will be fabricated. FIG. 1 depicts a cross-sectional view Y taken at corresponding section line Y of inset 103. Inset 103 shows gates 131 with side spacers 133 and source/drain regions 118, 120 for reference. Source/drain regions 118 depict PFETs while source/drain regions 120 depict NFETs. Gates 131 run transversely to the source/drain regions 118, 120. Transistor channels are provided at intersections of gates 131 and the source/drain regions 118, 120 for the transistor devices.

The substrate 105 can include any suitable substrate structure, e.g., a bulk semiconductor, a semiconductor-on-insulator (SOI) substrate, etc., and preferably includes a monocrystalline semiconductor. In one example, the substrate 105 can include a silicon-containing material. Illustrative examples of Si-containing materials suitable for the substrate portion 106 can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

An etch stop layer 104 formed on the substrate 105 separates substrate portions 102 and 106. The etch stop layer 104 can include an epitaxially grown crystal structure. The etch stop layer 104 includes a material that permits the selective etching and removal of the substrate portion 102 in later steps. In one embodiment, the etch stop layer 104 includes SiGe although depending on the material of the substrate 105, other materials can be selected, e.g., SiGeC, SiC, etc. The substrate portion 102 can include a same material as the substrate portion 106, although other semiconductor materials can be employed, e.g., SiGe, SiGeC, SiC, etc.

A layer stack or stacks (not shown) are applied to or formed on the substrate portion 106. In one embodiment, one or more nanosheets (NS) are applied to the substrate portion 106. In another embodiment, the layer stacks can be epitaxially grown using different chemistries to form layers having different properties. The nanosheet or sheets can be patterned to expose and etch the substrate portion 106.

Substrate portion 106 is etched to form dielectric liner 108 and shallow trenches which are filled to form shallow trench isolation (STI) or STI regions 110. Dielectric liner 108 and STI 110 can be formed by depositing dielectric material, such as, e.g., SiO₂, SiOₓN_{y}, SiCO or other suitable compounds using, e.g., chemical vapor deposition (CVD), although other deposition methods can be employed.

Sacrificial placeholders 112, source/drain regions 118, 120, gates 131, interlevel dielectric layer 122 and contact holes 126 are formed by a number of processes. For example, the gates 131 can be formed using a dummy gate replacement method. The dummy gate material can include a polysilicon, amorphous Si or other selectively removeable material. The regions of the dummy gates have a high dielectric constant (high-K) gate dielectric formed. The dummy gate materials is removed and replaced by a gate metal fill. This process is known as a High-K Metal Gate (HKMG) process to form a gate structure for selectively activating FETs.

The sacrificial placeholders 112 can be epitaxially grown in trenches formed in substrate portion 106. The sacrificial placeholder 112 can include SiGe or other epitaxial grown material that can be selectively removed relative to surrounding materials.

An epitaxial growth process is performed to form source/drain regions 118, 119 and 120. Source/drain regions 118, 119 and 120 can include doped Si or SiGe and include faceted surfaces when epitaxial growth is not confined. In one embodiment, the source/drain regions 118, 119 and 120 can be designated as P-type or N-type devices, respectively. The P-type and N-type devices can have different materials selected for the source/drain regions 118, 119 and 120. For example, if the source/drain region 118 is a PFET, boron doped SiGe can be employed. For example, if the source/drain regions 119, 120 are NFETs, phosphorous doped Si can be employed. The source/drain regions 118, 119 and 120 can be appropriately doped during their formation, e.g., during epitaxial growth. It should be understood that other dopants and materials can be employed for the source/drain regions 118, 119 and 120. As shown, P-type and N-type devices can be formed adjacent to one another. Processing could include forming one device type and then the other device type by employing block masks to protect each device during processing of the other.

A dielectric layer 122, such as, e.g., an interlevel dielectric layer (ILD) is formed. The dielectric layer 122 can include any suitable material, e.g., silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C: H). The dielectric layer 122 can be deposited using CVD, although other deposition methods can be employed. A planarization process, e.g., chemical mechanical polishing (CMP), can be employed to level off the free surface of the dielectric layer 122.

Openings 126 for topside source/drain region contacts are formed to make connections to the source/drain regions 118 and 120. A patternable material is deposited or spun onto a surface of the wafer 100 over dielectric layer 122. In one embodiment, an organic planarization layer (OPL) 124 is formed over the wafer 100. In some embodiments, an anti-reflective coating (ARC) layer (not shown) may be formed on the OPL 124 followed by a layer of photoresist formed on the ARC layer. The layer of photoresist can be imaged with an image pattern and developed to form an etch mask.

The OPL 124 can be etched in accordance with the etch mask to open up openings 126 in the OPL 124 that expose the source/drain regions 118, 120. The openings 126 are accurately controlled by an anisotropic etch, e.g., a reactive ion etch (RIE) etch or ion beam etch (IBE etch).

The OPL 124 is stripped or removed from the wafer 100. The OPL can be removed by employing an ashing process. Alternately, the OPL is left, and an additional mask layer is formed over it to pattern contact extensions.

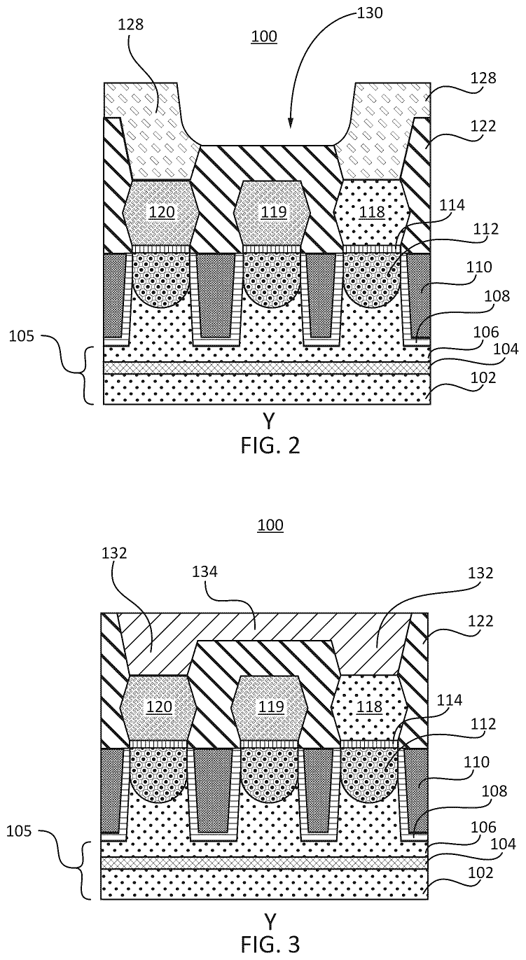

Referring to FIG. 2, in one embodiment, an additional mask 128 is formed to fill openings 126 and span over source/drain regions 118, 119, 120 when the previous OPL 124 was removed. Otherwise, additional material is added to form additional mask 128. In one embodiment, the mask 128 includes an OPL. In some embodiments, an anti-reflective coating (ARC) layer (not shown) may be formed on the mask 128 followed by a layer of photoresist formed on the ARC layer. The layer of photoresist can be imaged with an image pattern and developed to form an etch mask. The mask 128 can be etched in accordance with the etch mask to open up the mask 128 to form a trench 130 employed for patterning a contact extension. The trench or opening 126 can be formed using an anisotropic etch, e.g., RIE or IBE.

The trench 130 spans over or flies over the source/drain region 119. In the illustrative embodiment described, the source/drain region 119 will include a bottom side contact and therefore does not include a topside contact. In this way, the space over the source/drain region 119 is available for other structures. Here, the space over the source/drain region 119 includes adequate dielectric material in the dielectric layer 122 between the source/drain region 119 and the trench 130 to ensure proper operation without shorting to nearby structures or the source/drain region 119 once a contact extension is formed.

It should be understood that a length of the contact extension 134 can span over more than one source/drain region or other structure(s). The additional mask 128 and/or OPL 124 is/are removed to expose the source/drain regions 118 and 120 to later form contacts. The additional mask 128 and/or OPL 124 can be removed by an ashing process.

Referring to FIG. 3, contacts 132 and contact extension(s) 134 are formed. Contacts 132 and contact extension(s) 134 can be integrally formed in a same conductive fill process (e.g., a damascene process). However, in other embodiments, the contacts 132 and contact extension 134 can be formed in separate fill processes. Contacts 132 make connections to the source/drain regions 118 and 120. The contact extension 134 spans over the source/drain region 119.

In useful embodiments, a silicide liner, such as Ti, Ni, NiPt can be deposited first, then a diffusion barrier can be formed in trenches for contacts 132 prior to the conductive fill. A diffusion barrier can also be employed for contact extension 134 prior to the conductive fill. The diffusion barrier can include, e.g., TiN, TaN, or similar materials. A conductive fill is performed to fill the trenches on top of the diffusion barrier, if present. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, plasma enhanced CVD (PECVD), atomic layer deposition (ALD) or any other suitable deposition method. The conductive fill is planarized, e.g., by CMP, to form contacts 132 and contact extension(s) 134.

After planarization, the contacts 132 and the contact extension 134 share a top surface and are disposed in a same level. The contact extension 134 is not a different metal line layer; instead, the contact extension occupies free space provided by the absence of a top contact to source/drain region 119.

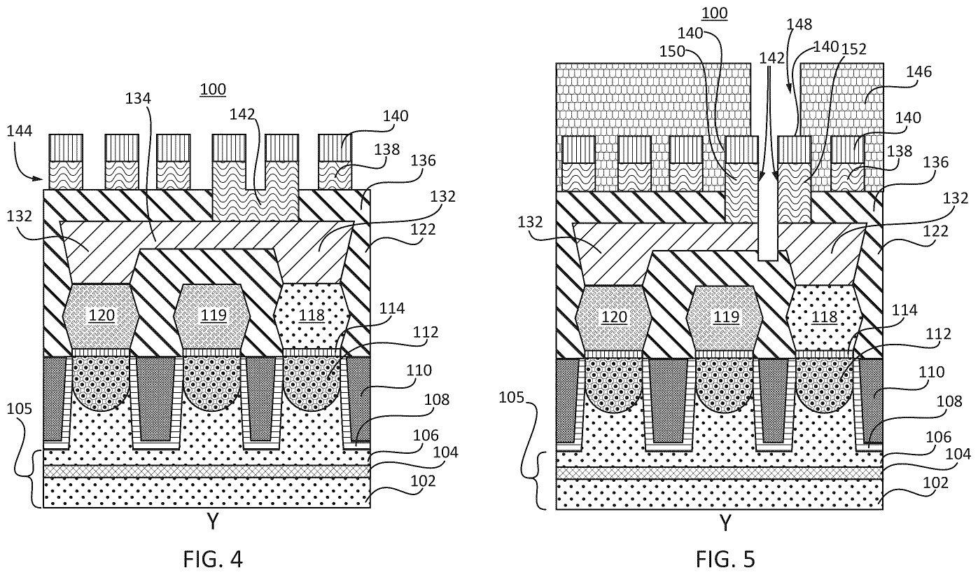

Referring to FIG. 4, a dielectric layer 136, such as, e.g., an interlevel dielectric layer (ILD) is formed over the contacts 132 and the contact extension 134. The dielectric layer 136 can include any suitable material, e.g., silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C: H). The dielectric layer 122 can be deposited using CVD, although other deposition methods can be employed. A planarization process, e.g., chemical mechanical polishing (CMP), can be employed to level off the free surface of the dielectric layer 136.

The dielectric layer 136 is patterned to form openings for vias 142 to be formed. Via 142 includes a merged via that has sufficient width to span over contact 132, over the source/drain region 118 and over the source/drain region 119. Via 142 is preferably centered between metal lines 138 formed in the next steps, as will be described.

In useful embodiments, a diffusion barrier can be formed in openings for vias 142. The diffusion barrier can include, e.g., TiN, TaN, or similar materials. A conductive fill is performed on top of the diffusion barrier, if present. A conductive layer 144 is deposited to fill the via hole and cover the dielectric layer 136. The conductive layer 144 can be used to form the via 142 as well as metal lines 138. The via 142 and metal lines 138 can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. In other embodiments, the via 142 and the metal lines 138 can be formed separately and include different conductive deposition steps. The conductive layer 144 is planarized, e.g., by CMP.

A mask 140 is formed and patterned over the conductive layer 144. The mask can include a hard mask, photoresist, OPL or any other mask suitable for etching the conductive layer 144. An etch process is performed in accordance with the pattern of the mask 140. The etch can include an anisotropic etch, such as, e.g., RIE. The etch process is subtractive and removes material to form metal lines 138 (e.g., M1 layer metal lines).

Referring to FIG. 5, the contact extension 134 can be cut to provide two or more circuit paths. A mask material 146 is formed over the wafer 100 and is patterned to form opening 148. The mask material 146 can include OPL or other suitable mask materials. An etch process, such as, a RIE process is performed to subtractively etch the via 142 through the metal lines 138 using mask 140 to protect the metal lines 138. The subtractive etch, in this embodiment, splits the via 142 into two portions 150 and 152. The subtractive etch process can continue to etch through the contact extension 134 to cut the contact extension 134. The contact extension 134 includes a portion that connects to source/drain region 118 and another portion that spans over the source/drain region 119 and connects to source/drain region 120.

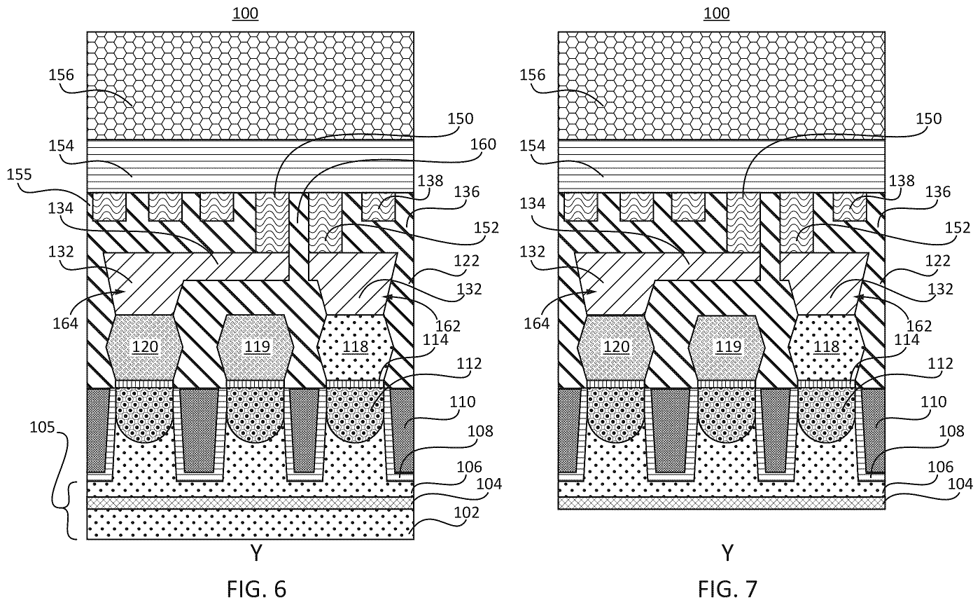

Referring to FIG. 6, mask material 146 is removed, e.g., by an OPL ashing process. A dielectric layer 155, such as, e.g., an interlevel dielectric layer (ILD) is formed to fill in between the metal lines 138 and form a cut plug 160. The dielectric layer 155 can include any suitable material, e.g., silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C: H). The dielectric layer 155 can be deposited using CVD, although other deposition methods can be employed. A planarization process, e.g., chemical mechanical polishing (CMP), can be employed to level off the free surface of the dielectric layer 155 and remove the mask 140 from the top surface of the metal lines 138.

The cut plug 160 electrically isolates a first circuit 162 from a second circuit 164. The first circuit 162 includes a metal line 138, via portion 152 of via 142, a portion of contact extension 134 and contact 132 connecting to source/drain region 118. The second circuit 164 includes a metal line 138, via portion 150 of via 142, a portion of contact extension 134, contact 132 connecting to source/drain region 120. In this way, a space over the source/drain region 119 is not left empty and instead provides for additional connective lines that can connect to upper metal layers. Here, the metal lines of M1 are illustratively depicted; however, metal lines or contacts from higher layers or structures in, e.g., a back end of the line (BEOL) layer 154 can be connected through the via 142 instead of or in addition to the connections to the M1 layer.

Processing continues with the formation of back end of the line (BEOL) structures in the BEOL layer 154, which can include metal structures and dielectric layers to complete the front side of the device and provide electrical access to the devices formed.

A carrier wafer 156 can be bonded to the BEOL layer 154. The carrier wafer 156 provides support and transportability to the wafer 100 for further processing which includes flipping the wafer 100 for processing the other side of the device.

Referring to FIG. 7, to continue processing, the wafer 100 can be flipped to process features on the bottom side of the device. However, for clarity and consistency, the device will be shown in the FIGS. in a same orientation as previously described with continued and consistent reference to bottom/top. The substrate portion 102 is removed from the bottom side of the device. The substrate portion 102 can be removed by an etch process that stops on the etch stop layer 104. In an alternate embodiment, a cleave process can be employed to propagate a crack to remove the substrate portion 102 at the etch stop layer 104.

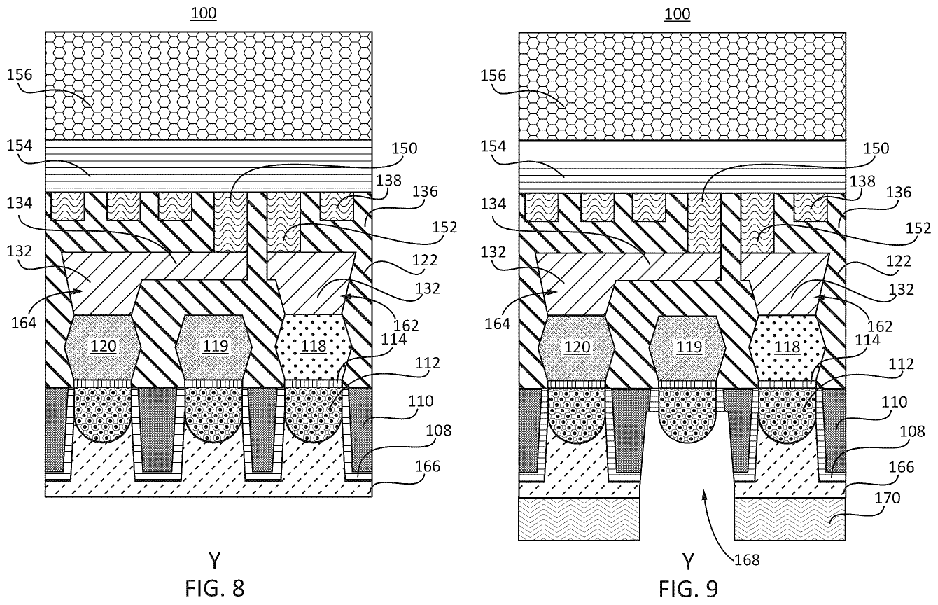

Referring to FIG. 8, the etch stop layer 104 is then removed by an etch process. In an alternate embodiment, a chemical mechanical polish (CMP) process can be employed. With the removal of the etch stop layer 104, the substrate portion 106 is exposed. The substrate portion 106 is removed by an etch process that selectively removes the material of the substrate portion 106 relative to the dielectric liner 108 and the sacrificial placeholder 112. The removal of the substrate portion 106 leaves the dielectric liner 108 and the sacrificial placeholders 112 exposed.

A dielectric layer 166 is formed over the dielectric liner 108 and the sacrificial placeholders 112. The dielectric layer 166 includes a material that is selectively removeable relative to the dielectric liner 108. For example, if the dielectric liner 108 includes a silicon oxide, dielectric layer 166 can include a silicon nitride or silicon oxynitride to be selectively etchable with respect to the dielectric liner 108. The dielectric layer 166 can include the same materials as dielectric layer 122. A CMP process can be employed to planarize the free surface of the dielectric layer 166.

Referring to FIG. 9, backside contacts are formed to make connections with the source/drain region 119. A patternable material 170 is deposited or spun onto a surface of the wafer 100 over dielectric layer 166. In one embodiment, an OPL is formed over the wafer 100 for patternable material 170. In some embodiments, an anti-reflective coating (ARC) layer (not shown) may be formed on the OPL followed by a layer of photoresist formed on the ARC layer. The layer of photoresist can be imaged with an image pattern and developed to form an etch mask. The dielectric layer 166 can be etched, e.g., using an anisotropic etch, in accordance with the etch mask formed by the patternable material to open up an opening 168 and expose sacrificial placeholder 112.

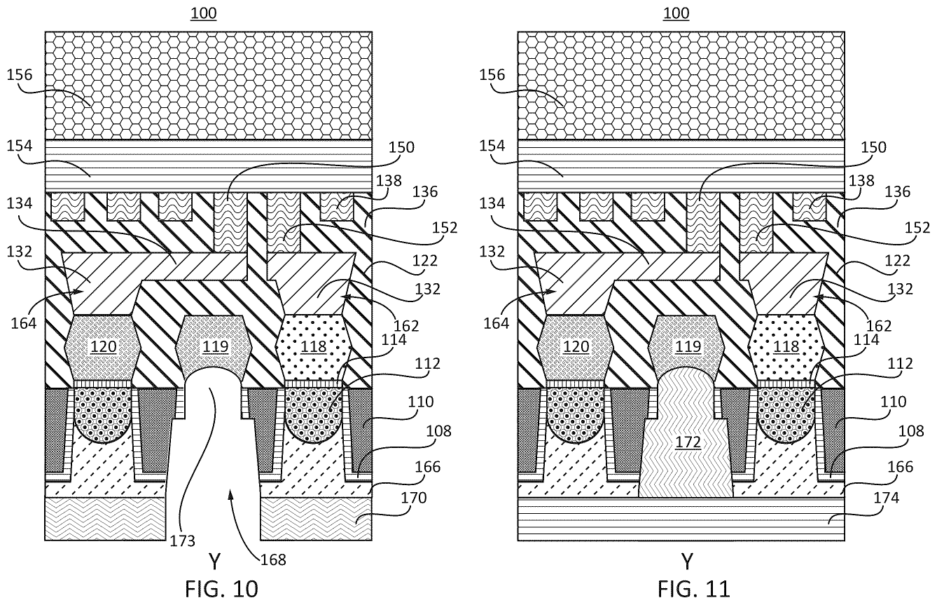

Referring to FIG. 10, etching can continue to remove the sacrificial placeholders 112 in opening 168 as well as portions of dielectric liner 108 and STI 110. Next, gouges 173 can optionally be formed in bottoms of the exposed source/drain region 119 by continuing to etch. The opening 168 is accurately controlled by an anisotropic etch, e.g., RIE or IBE. The anisotropic etch, such as a plasma dry etch, is accurately controlled since a lithographic process is employed.

The patternable material 170 is stripped or removed from the wafer 100. If OPL is employed, the OPL can be removed by employing an ashing process. A pre-silicide clean process can be performed to clean surfaces in preparation for siliciding exposed surfaces of the source/drain region 119.

In useful embodiments, a silicide liner, such as Ti, Ni, NiPt is deposited first, then a diffusion barrier can be formed in the openings 168 prior to a conductive fill. The diffusion barrier can include, e.g., TiN, TaN, or similar materials.

Referring to FIG. 11, a conductive fill is performed to fill the opening 168. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form a contact 172. Contact 172 connects to the source/drain region 119 from a bottom side. The bottom side contact 172 permits space to from the contact extension 134 to be employed over the source/drain region 119.

A backside interconnect layer 174 will be employed to form metal structures and dielectric layers to complete the bottom side of the device and provide electrical access to the devices formed. The backside interconnect layer 174 can be employed to form backside power rails (BPR) for a backside power distribution network (BSPDN). The backside interconnect layer 174 is formed on the dielectric layer 166 and connects to the contact 172.

The backside interconnect layer 174 can include a deposition of one or more metal layers. In one embodiment, the metal layer can include Ru, although other metals can be employed, e.g., Cu, W, Mo, Rh, Ir, etc. The backside interconnect layer 174 can be deposited by a CVD deposition process, although deposition processes can be employed.

A BSPDN can be formed on the backside interconnect layer 174 and processing can continue to complete the device.

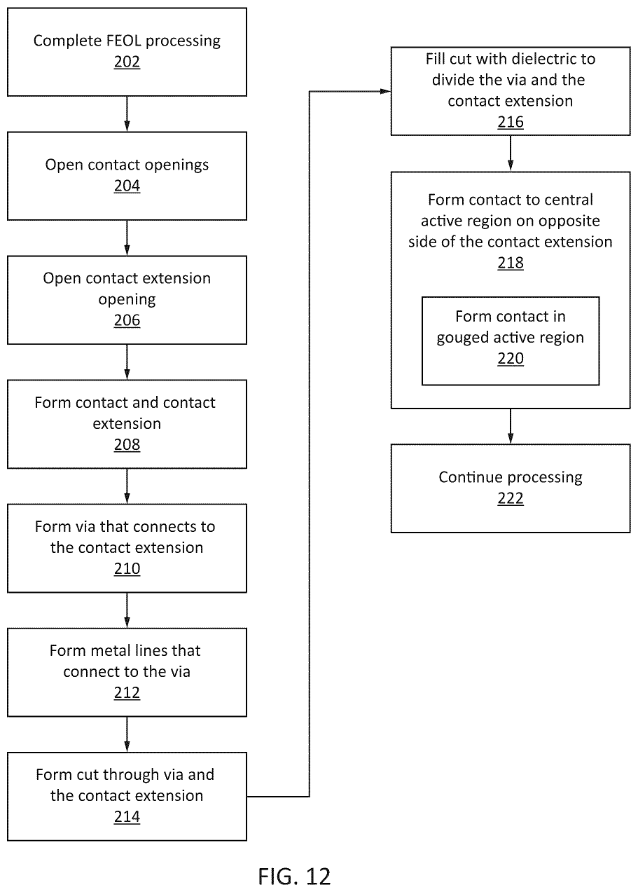

Referring to FIG. 12, methods for fabrication of a semiconductor device are described in accordance with embodiment of the present invention. In block 202, a wafer/semiconductor device having a substrate includes front end of the line (FEOL) processing performed up to a point where source/drain regions are buried within a planarized dielectric layer (e.g., ILD). In block 204, contact openings are opened in the dielectric layer to expose outer source/drain regions on a first side at a first level of the device. In block 206, a contact extension opening is patterned in communication with the contact openings in the dielectric layer. The contact extension opening spans over a central source/drain region disposed between the outer source/drain regions. In other embodiments, additional central source/drain regions or other structures may be spanned over by a length of the contact extension.

In block 208, contacts are formed in the contact openings and a contact extension is formed in the contact extension opening. This process can concurrently form the contacts and the contact extension. In this way, the contacts and the contact extension can be integrally formed. In other embodiments, the contacts and the contact extension can be formed in separate processes. In one embodiment, the contact openings and the contact extension opening are filled with conductive material, which is planarized to form a shared top surface for the contacts and the contact extension. The contacts and the contact extension are disposed within a same level.

In block 210, a via that connects the contact extension to upper metal structures is formed. The via is formed at a higher level than the contact extension and connects to a top portion of the contact extension. In one embodiment, the via is a merged via to provide additional width to the via. In block 212, metal lines for the upper metal structures that connect to the via are formed. These metal lines can be, e.g., M1 lines, M2 lines or any other upper metal structures.

In block 214, a cut is formed through the via and through the contact extension. In one embodiment, the cut is positioned in between the metal lines. The cut is formed by subtractive etching of the via and the contact extension. The cut extends into the dielectric layer therebelow. In block 216, the cut is filled with a dielectric material to electrically isolate portions of the via and the contact extension to form at least two signal paths to the outer source/drain regions from the upper metal structures above the first level. The cut divides the via such that portions of the via are disposed in separate signal paths. The merged via permits more conductive material for the connections between metal lines and the contacts and/or contact extension. For example, the merged via includes a portion over the contact extension and a portion over one of the outer source/drain regions. The cut also divides the contact extension between separate signal paths.

In block 218, a contact to the central source/drain region at a second side opposite the first side can be formed. The contact extension provides a wiring opportunity in a space between the contact extension and the central source/drain region. In one embodiment, this space availability is as a result of a second side access contact instead of on the first side.

In block 220, the contact can be formed by exposing the central source/drain region on the second side and gouging the central source/drain region on the second side. The contact is formed in a gouged portion of the central source/drain region.

In block 222, processing continues with e.g., the formation of a backside interconnect layer, power distribution network, etc.

Exemplary applications/uses to which the present invention can be applied include, but are not limited to, semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher-level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising.” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below”, or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
source/drain regions disposed at a first level;
contacts connecting to the source/drain regions on a first side of the source/drain regions;
a contact extension having end portions connected to the contacts and a length spanning a distance between the contacts; and
a cut plug disposed through the length and electrically isolating portions of the contact extension to form at least two signal paths to the source/drain regions from a metal layer above the first level.

2. The semiconductor device as recited in claim 1, wherein the contacts and the contact extension share a top surface.

3. The semiconductor device as recited in claim 1, wherein the length of the contact extension spans over at least one source/drain region.

4. The semiconductor device as recited in claim 3, wherein the at least one source/drain region includes a contact at a second side opposite the first side.

5. The semiconductor device as recited in claim 1, wherein the cut plug is formed through a via, and the via is divided such that portions of the via are electrically isolated from one another and disposed within the at least two signal paths.

6. The semiconductor device as recited in claim 5, wherein the cut plug is formed between two metal lines of the metal layer above the first level.

7. The semiconductor device as recited in claim 1, wherein the contacts and the contact extension are integrally formed.

8. A semiconductor device, comprising:
a central source/drain region disposed between outer source/drain regions at a first level;
contacts connecting to the outer source/drain regions on a first side of the outer source/drain regions;
a contact extension having end portions connected to the contacts and a length spanning a distance between the contacts and over the central source/drain region;
a via connecting the contact extension to upper metal structures; and
a cut plug disposed through the via and the length to electrically isolate portions of the via and the contact extension to form at least two signal paths to the outer source/drain regions from the upper metal structures above the first level.

9. The semiconductor device as recited in claim 8, wherein the contacts and the contact extension share a top surface.

10. The semiconductor device as recited in claim 8, wherein the central source/drain region includes a contact at a second side, opposite the first side.

11. The semiconductor device as recited in claim 8, wherein the upper metal structures include metal lines and the cut plug is formed between two metal lines above the first level.

12. The semiconductor device as recited in claim 8, wherein the contacts and the contact extension are integrally formed.

13. A method for fabrication of a semiconductor device, comprising:
opening up contact openings in a dielectric layer to expose outer source/drain regions on a first side at a first level;
patterning a contact extension opening in communication with the contact openings in the dielectric layer, the contact extension opening spanning over a central source/drain region disposed between the outer source/drain regions;
forming contacts in the contact openings and a contact extension in the contact extension opening;
forming a via that connects the contact extension to upper metal structures;
forming metal lines for the upper metal structures that connect to the via;
subtractive etching a cut between the metal lines, through the via and through the contact extension; and
filling the cut with a dielectric material to electrically isolate portions of the via and the contact extension to form at least two signal paths to the outer source/drain regions from the upper metal structures above the first level.

14. The method as recited in claim 13, wherein forming the contacts in the contact openings and the contact extension in the contact extension opening includes:
filling the contact openings and the contact extension opening with conductive material; and
planarizing the conductive material to form a shared top surface for the contacts and the contact extension.

15. The method as recited in claim 13, wherein filling the cut with the dielectric material includes dividing the via such that portions of the via are disposed in separate signal paths.

16. The method as recited in claim 13, wherein the contacts and the contact extension are integrally formed.

17. The method as recited in claim 13, wherein the contacts and the contact extension are disposed within a same level.

18. The method as recited in claim 13, wherein forming the via includes forming a merged via having a portion over the contact extension and a portion over one of the outer source/drain regions.

19. The method as recited in claim 13, further comprising forming a contact to the central source/drain region at a second side opposite the first side.

20. The method as recited in claim 19, wherein forming the contact further comprises:
exposing the central source/drain region on the second side;
gouging the central source/drain region on the second side; and
forming the contact in a gouged portion of the central source/drain region.
